(19) United States
(12) Patent Application Publication
(10) Pub. No.: US 2020/0045153 A1
(43) Pub. Date: Feb. 6, 2020

(54) METHOD FOR PROCESSING HOUSING OF ELECTRONIC DEVICE AND HOUSING MADE

(71) Applicants: SHENZHEN FUTAIHONG PRECISION INDUSTRY CO., LTD., Shenzhen (CN); FIH (HONG KONG) LIMITED, Kowloon (HK)

(72) Inventors: CHUN-XU XIE, Shenzhen (CN); PAN HU, Shenzhen (CN); YI XIONG, Shenzhen (CN); ZHI HE, Shenzhen (CN); ZHENG-GANG XIE, Shenzhen (CN)

(21) Appl. No.: 16/253,162

(22) Filed: Jan. 21, 2019

(30) Foreign Application Priority Data
Aug. 3, 2018 (CN) 201810878080.9

(51) Int. Cl. H04M 1/02; H05K 5/04; H05K 5/03

(52) U.S. Cl. CPC H04M 1/0266; H04M 1/0249; H05K 5/03; H05K 5/04

(57) ABSTRACT

A method for processing during manufacture a housing of electronic device is disclosed. The housing includes a metal middle frame and a glass cover and UB epoxy resin is infilled into a gap between the metal middle frame and the glass cover, the joint being seamlessly bonded. Any overflow of resin is easily removed.

### FIELD

The present disclosure provides a method for processing housing of electronic device and housing produced by the method.

### BACKGROUND

A metal middle frame and a glass cover are glued together during production of the mobile phone shell. When the glue is dispensed, there may be overflowing glue and the amount of overflow can often be difficult to control. The glue is often dispensed unevenly, and the excess glue is often not easy to remove. Since the glass cover is coated with an AF (Anti-fingerprint) layer, the optical effects of the cover and glue adhesion may be affected. Different glues may cause other problems, such as uneven flow, insufficient gloss after polishing, or too much glue overflow. Improvement in the art is preferred.

### BRIEF DESCRIPTION OF THE DRAWINGS

Implementations of the present disclosure will now be described, by way of example only, with reference to the attached figures.

FIG. 1 is a flow chart of a method for processing a housing of an electronic device during manufacture according to an embodiment of the present disclosure.

FIG. 2 is a cross-section structural view of a film covered on an outer surface of the metal middle frame and the glass cover according to an embodiment of the present disclosure.

FIG. 3 is a cross-section structural view of a housing of the electronic device according to an embodiment of the present disclosure.

FIG. 4 is a schematic diagram showing an overall structure of the housing of the electronic device shown in FIG. 3.

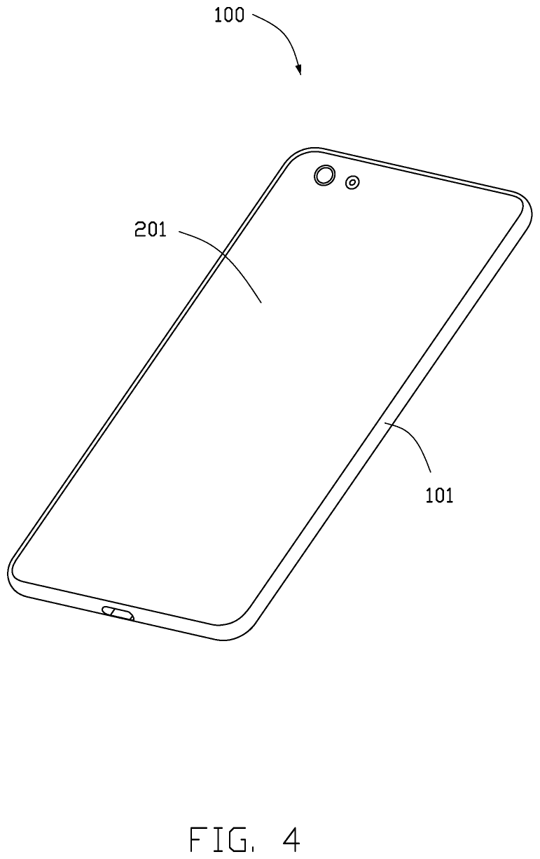

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiment described herein can be practiced without these specific details. In other instances, methods, procedures, and components have not been described in detail so as not to obscure the related relevant feature being described. Further, the description is not to be considered as limiting the scope of the embodiments described herein. The drawings are not necessarily to scale and the proportions of certain parts may be exaggerated to better illustrate details and features of the present disclosure.

Unless otherwise defined, all technical and scientific terms used herein has the same meaning as commonly understood by those skilled in the art to which the present disclosure pertains. The terms used in the description of the present disclosure are for the purpose of describing the specific embodiments and are not intended to limit the disclosure.

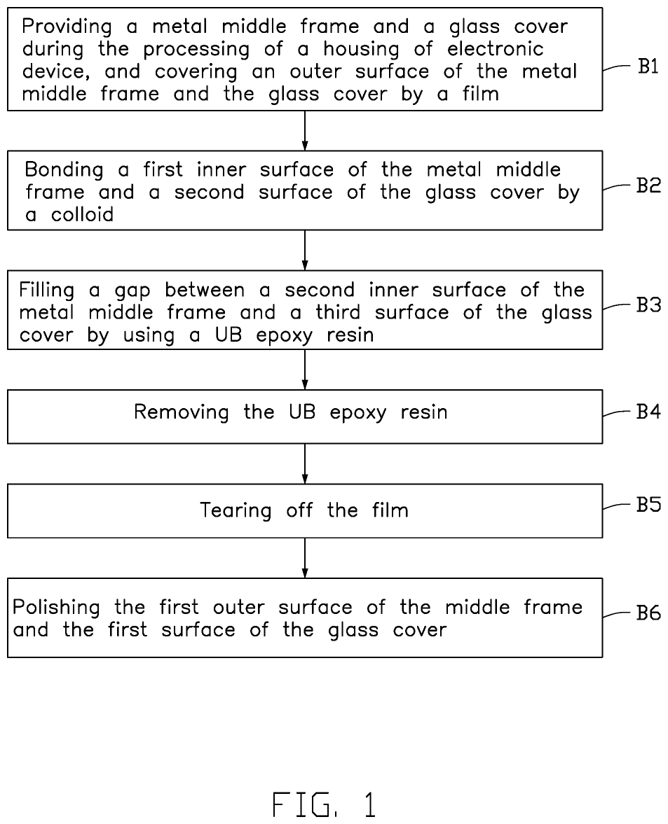

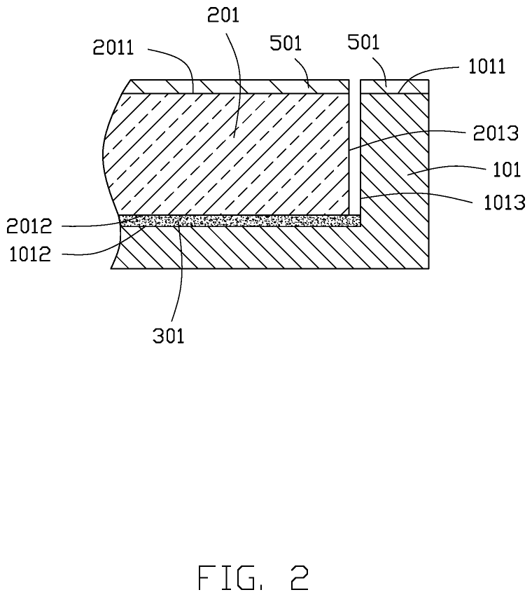

Referring to FIG. 1 and FIG. 2, one embodiment of the present disclosure provides a method for processing housing of electronic device. The method creates a seamless joint between a metal middle frame and a glass cover, and the method includes the following blocks:

At block B1, providing a metal middle frame 101 and a glass cover 201 during the processing of a housing of electronic device, such as a housing of a mobile phone, a tablet computer and the like. And covering an outer surface of the metal middle frame 101 and the glass cover 201 by a film 501.

The metal middle frame 101 includes a first outer surface 1011, a first inner surface 1012, and a second inner surface 1013. The first outer surface 1011 and the first inner surface 1012 are connected by the second inner surface 1013. Cross-section of the metal middle frame 101 is L-shaped.

The glass cover 201 is plate-shaped, and includes a first surface 2011, a second surface 2012 facing away from the first surface 2011, and a third surface 2013. The first surface 2011 and the second surface 2012 are connected by the third surface 2013.

The glass cover 201 is disposed inside the metal middle frame 101. The second surface 2012 of the glass cover 201 and the first inner surface 1012 of the metal middle frame 101 form a pair of opposing surfaces. The third surface 2013 of the cover glass 201 and the second inner surface 1013 of the metal middle frame 101 form another pair of opposing surfaces. There is a gap between the third surface 2013 of the glass cover 201 and the second inner surface 1013 of the metal middle frame 101, and a width of the gap is about 0.1 to about 0.25 mm. The third surface 2013 of the glass cover 201 and the second inner surface 1013 are thus separated by about 0.1 to about 0.25 mm.

All surfaces of the metal middle frame 101 have been anodized, and the outer surface and the periphery of the glass cover 201 have been plated with an AF layer.

The first outer surface 1011 of the metal middle frame 101 and the first surface 2011 of the glass cover 201 are covered by a film 501. The film 501 protects the first outer surface 1011 of the metal middle frame 101 and the first surface 2011 of the glass cover 201, and prevents contamination during gluing.

The present disclosure does not include detail explanation on the processing and improvement of other surfaces of the metal middle frame 101 and the cover glass 201, a description of other surfaces is therefore omitted.

At block B2, bonding the first inner surface 1012 of the metal middle frame 101 and the second surface 2012 of the glass cover 201 by a colloid 301. The colloid 301 is selected from one or more of double-sided tape or elastic glue.

At block B3, filling a gap between the second inner surface 1013 of the metal middle frame 101 and the third surface 2013 of the glass cover 201 by using a UB epoxy resin 401. The color of the UB epoxy resin 401 may be gloss black, gloss white or transparent. The UB epoxy resin 401 is easy to cure, and the volume of the UB epoxy resin 401 does not change significantly during curing. The curing temperature range of the UB epoxy resin 401 is about 90˜110° C., and the curing time range of the UB epoxy resin 401 is about 60˜120 min.

At block B4, removing UB epoxy resin 401 which may have overflowed onto the first outer surface 1011 of the metal middle frame 101 and the first surface 2011 of the glass cover 201. The removal may be by scraping or polishing and the removal of the glue may be during or after curing of the glue.

At block B5, tearing off the film 501 protecting the first outer surface 1011 of the metal middle frame 101 and the first surface 2011 of the glass cover 201. The film 501 may be an artificial tear film or an automatic tear film.

At block B6, polishing the first outer surface 1011 of the middle frame 101 and the first surface 2011 of the glass cover 201 after applying the UB epoxy resin 401, so that the first outer surface 1011 of the metal middle frame 101, the first surface 2011 of the glass cover 201, and the UB epoxy resin 401 form a flat and uninterrupted surface. That is, the first outer surface 1011 of the metal middle frame 101, the first surface 2011 of the glass cover 201, and the UB epoxy resin 401 are flush, achieving a continuous, high-gloss appearance.

Preferably, the color of the UB epoxy resin 401 in the block B3 is gloss black, the curing temperature is 90° C., and the curing time is 60 min.

Preferably, the manner of removing the overflow glue in the block B4 is by polishing, and the removal of the overflowed glue is during the process of glue curing.

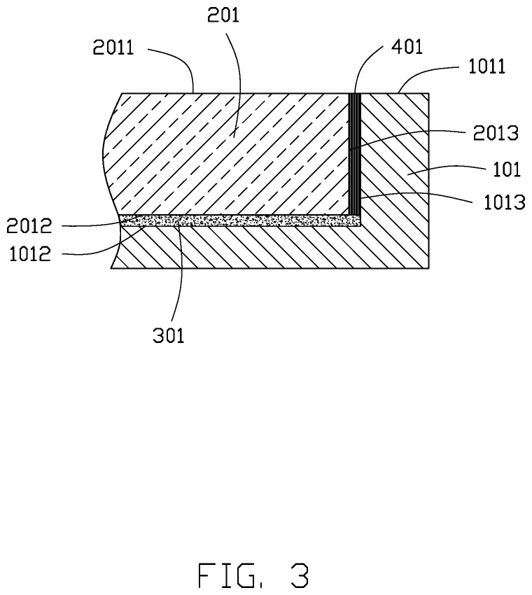

Referring to FIG. 2 and FIG. 3, the present disclosure further provides a housing 100 of electronic device, such as a housing of a mobile phone. The housing 100 includes a metal middle frame 101 and a glass cover 201. Specifically, the cross-section of the metal middle frame 101 is substantially L-shaped. The metal middle frame 101 includes a first outer surface 1011, a first inner surface 1012, and a second inner surface 1013. The first outer surface 1011 and the first inner surface 1012 are connected by the second inner surface 1013. The metal middle frame 101 can be made of titanium alloy, stainless steel, steel-aluminum composite die-casting, aluminum alloy, and the like.

All surfaces of the metal middle frame 101 are anodized, the main function of the anodizing is to form an oxide film on the metal surface. Anodizing overcomes any defects in uniform surface hardness and renders a high wear resistance, being also aesthetically pleasing and with properties of an insulator.

The glass cover plate 201 is plate-shaped. The outer surface and the periphery of the glass cover 201 are plated with an AF layer in order to increase hydrophobicity, oil rejection, and antifouling performance of the screen, and give wear resistance and high light transmission. The glass cover 201 includes a first surface 2011, a second surface 2012, and a third surface 2013, where the first surface 2011 and the second surface 2012 are connected by the third surface 2013, and the first surface 2011 is opposite to the second surface 2012.

The second surface 2012 of the glass cover 201 is supported on the second inner surface 1013 of the metal middle frame 101. The second surface 2012 of the glass cover 201 is bonded to the second inner surface 1013 of the metal middle frame 101 by a colloid 301, which is one of double-sided tape or elastic glue. The gap size between the third surface 2013 of the glass cover 201 and the second inner surface 1013 of the metal middle frame 101 is about 0.1-0.25 mm, and such gap is filled with UB epoxy resin 401. The UB epoxy resin 401 provides a flat and uniform bond between the metal middle frame 101 and the glass cover 201, residual UB epoxy resin 401 is easy to remove, and polishing to a high gloss is possible. The removal of residual glue leaves a flat and continuous surface, for a better appearance of the housing 100.

The UB epoxy resin 401 is easy to cure, and curing produces no significant change in volume. The bonding of the first outer surface 1011 of the metal middle frame 101 and the first surface 2011 of the glass cover 201 by UB epoxy resin 401 can be seamless.

The amount of UB epoxy resin 401 can be controlled when dispensing, so that the UB epoxy resin 401 evenly penetrates into the gap, and the flow is uniform. The gap between the metal middle frame 101 and the glass cover 201 can be completely filled with the UB epoxy resin 401, and the same can be given a high gloss appearance after polishing.

It is to be understood, however, that even through numerous characteristics and advantages of the present disclosure have been set forth in the foregoing description, together with details of assembly and function, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. A processing method of a housing of an electronic device, comprising:
providing a metal middle frame and a glass cover, and covering an outer surface of the metal middle frame and the glass cover by a film;
bonding a pair of opposite surfaces of the metal middle frame and the glass cover by a colloid;
filling a gap between another pair of opposite surfaces of the metal middle frame and the glass cover with UB epoxy resin;
removing the UB epoxy resin which have overflowed onto the outer surface of the metal middle frame and the glass cover;
tearing off the film; and
polishing the outer surface of the metal middle frame and the glass cover.

2. The processing method of a housing of an electronic device as claimed in claim 1, wherein all surfaces of the metal middle frame are anodized.

3. The processing method of a housing of an electronic device as claimed in claim 1, wherein the outer surface and a periphery of the glass cover are plated with an anti-fingerprint layer.

4. The processing method of a housing of an electronic device as claimed in claim 1, wherein a cross-section of the metal middle frame is L-shaped, and the metal middle frame includes a first outer surface, a first inner surface and a second inner surface, the first inner surface is connected to the first outer surface and the second inner surface; and the first outer surface, the second inner surface and the first inner surface are connected, the glass cover is plate-shaped and includes a first surface, a second surface, and a third surface. The first surface and the second surface are connected by the third surface, and the first surface facing away from the second surface, the pair of opposite surfaces bonded by the colloid is the second inner surface of the metal middle frame and the second surface of the glass cover, the pair of opposite surfaces filling the gap with the UB epoxy resin is the first inner surface of the metal middle frame and the third surface of the glass cover.

5. The processing method of a housing of an electronic device as claimed in claim 4, wherein the first outer surface of the metal middle frame and the first surface of the glass cover are shielded by a film.

6. The processing method of a housing of an electronic device as claimed in claim 1, wherein the curing temperature range of the UB epoxy resin is about 90˜110° C., and the curing time range of the UB epoxy resin is about 60˜120 min.

7. A housing of an electronic device comprising:
a metal middle frame; and
a glass cover, one pair of opposite surfaces of the metal middle frame and the glass cover are bonded by colloid, and the other pair of opposite surfaces are filled with UB epoxy resin.

8. The housing as claimed in claim 7, wherein the cross-section of the metal middle frame is L-shaped and the glass cover is plate-shaped, the glass cover is placed inside the metal middle frame.

9. The housing as claimed in claim 8, wherein the metal middle frame includes a first outer surface, a first inner surface and a second inner surface, the first inner surface is connected to the first outer surface and the second inner surface, and the first outer surface, the second inner surface, and the first inner surface are connected, the glass cover includes a first surface, a second surface, and a third surface, the first surface and the second surface are connected by the third surface, and the first surface is opposite to the second surface, the pair of opposite surfaces bonded by the colloid is the second inner surface of the metal middle frame and the second surface of the glass cover, the pair of opposite surfaces filling the gap with the UB epoxy resin is the first inner surface of the metal middle frame and the third surface of the glass cover.

10. The housing as claimed in claim 9, wherein the first outer surface of the metal middle frame, the first surface of the glass cover and the UB epoxy resin form a continuous surface.
